(19) United States
(12) Patent Application Publication
(10) Pub. No.: US 2017/0110630 A1
(43) Pub. Date: Apr. 20, 2017

(54) SEMICONDUCTOR LIGHT EMITTING ELEMENT, PRODUCTION METHOD THEREFOR, LED ELEMENT AND ELECTRON-BEAM-PUMPED LIGHT SOURCE DEVICE

(71) Applicant: USHIO DENKI KABUSHIKI KAISHA, Tokyo (JP)

(72) Inventors: Yoichi KAWAKAMI, Kyoto-shi (JP); Mitsuru FUNATO, Kyoto-shi (JP); Ken KATAOKA, Tokyo (JP); Masanori YAMAGUCHI, Himeji-shi (JP)

(73) Assignee: USHIO DENKI KABUSHIKI KAISHA, Tokyo (JP)

(21) Appl. No.: 15/129,181

(22) PCT Filed: Mar. 31, 2015
(86) PCT No.: PCT/JP2015/060101

§ 371 Date: Sep. 26, 2016

(30) Foreign Application Priority Data
Mar. 31, 2014 (JP) 2014-074165

(51) Int. Cl. H01L 33/32; H01L 33/06; H01L 33/24; H01L 33/00; H01L 33/16

(52) U.S. Cl. CPC H01L 33/32; H01L 33/007; H01L 33/16; H01L 33/24; H01L 33/06

(57) ABSTRACT

This method for producing a semiconductor light emitting element includes: a step (a) of preparing a growth substrate; a step (b) of growing a first layer made of Alₓ₁Ga_{y1}In_{1-x1-y1}N (0<x1≦1, 0≦y1≦1) on an upper layer of the growth substrate in a <0001> direction; a step (c) of forming a groove portion extending along a <11-20> direction of the first layer with respect to the first layer with such a depth that a surface of the growth substrate is not exposed; a step (d) of growing a second layer made of Alₓ₂Ga_{y2}In_{1-x2-y2}N (0<x2≦1, 0≦y2≦1) on an upper layer of the first layer with at least a {1-101} plane serving as a crystal growth plane; and a step (e) of growing an active layer on an upper layer of the second layer.

### TECHNICAL FIELD

The present invention relates to a semiconductor light emitting element and relates particularly to a semiconductor light emitting element including a nitride semiconductor. Further, the present invention relates to a method for producing the semiconductor light emitting element and an electron-beam-pumped light source device and an LED element including the semiconductor light emitting element.

### BACKGROUND ART

In a semiconductor light emitting element made of a nitride semiconductor, there is a problem that light emitting efficiency is reduced due to an internal electric field, and at present, a solution to this problem has been discussed.

A nitride semiconductor such as GaN or AlGaN has a wurtzite crystal structure (hexagonal structure). FIG. 11 schematically shows a unit lattice of GaN crystal. Note that AlₓGa_{y}In_{1-x-y}N (0≦x≦1, 0≦y≦1) crystal shows a state in which at least some of Ga atoms shown in FIG. 11 are substituted with Al or In.

FIG. 12 is a view for explaining a plane direction of a wurtzite crystal structure. As shown in FIG. 12, the plane direction of the wurtzite crystal structure is expressed using basic vectors denoted by a1, a2, a3, and c in four-digit indices (hexagonal indices). The basic vector c extends in a [0001] direction, and this direction is called a “c-axis”. A plane perpendicular to the c-axis is called a “c-plane” or a (0001) plane.

Conventionally, a semiconductor light emitting element has been formed by c-plane growing with the use of a nitride semiconductor. The “c-plane growth” means epitaxial growth in a direction perpendicular to the c-plane, that is, along the c-axis.

As shown in FIGS. 11 and 12, in the c-axis direction, the Ga atom and an N atom are arranged asymmetrically. In this state, in the c-plane which is a growth plane of a GaN layer, a Ga atomic plane containing only the Ga atoms is slightly charged positively whereas an N atomic plane containing only N atoms is slightly charged negatively with the result that spontaneous polarization is produced in the c-axis direction. When a heterogeneous semiconductor layer is heteroepitaxially grown on a GaN crystal layer, compression strain or tensile strain is produced in the GaN crystal due to a difference in lattice constant between them, thereby producing piezoelectric polarization in the c-axis direction in the GaN crystal.

An active layer generally has a quantum well structure. When the quantum well structure is formed, the heteroepitaxial growth is required. Thus, when a semiconductor layer including an active layer with a c-plane serving as a growth plane has been grown, an internal electric field due to spontaneous polarization and piezoelectric polarization is generated in a quantum well in the c-axis direction. Due to this, the probability of recombination of electrons and holes is decreased to reduce light emitting efficiency.

In response to this problem, as means that improves the reduction in the light emitting efficiency due to the internal electric field in a nitride semiconductor, research is being conducted to develop a semiconductor light emitting element in which a plane (nonpolar plane) perpendicular to a c-plane or a plane (semipolar plane) inclined to the c-plane serves as a growth plane. For example, Patent Document 1 discloses an optoelectronic component formed by growing a quantum well structure on a side facet of a GaN layer and more specifically on a {1-101} crystal plane, a {11-20} crystal plane, a {1-100} crystal plane, or a {11-22} crystal plane.

In this specification, the signs “-” given immediately before the numerals in parentheses representing the Miller's indices represent the inversions of the indices and are synonymous with “bars” in the drawings.

### PRIOR ART DOCUMENT

### Patent Document

Patent Document 1: JP-A-2006-74050

### SUMMARY OF THE INVENTION

### Problems to be Solved by the Invention

FIGS. 13(a) and 13(b) are views for explaining an influence of an internal electric field on an energy band of an active layer. FIG. 13(a) is a view schematically showing an energy band diagram of the active layer grown on a c-plane, and FIG. 13(b) is a view schematically showing an energy band diagram of the active layer grown on an m-plane ({10-10} plane) which is a nonpolar plane.

FIGS. 13(a) and 13(b) exemplify a case where the active layer includes a barrier layer including an MN layer and a light emitting layer including an AlGaN layer. Such an active layer emits light in an ultraviolet region.

In an optical device, electrons and holes are combined in an active layer, and energy is released as light, whereby light is emitted. As described above, when an active layer is formed by c-plane growing, an internal electric field is generated in the active layer. Since the electrons and holes are electrically opposite, the internal electric field acts as a force applied in a direction in which the electrons and holes are spatially separated. Specifically, a wave function 103 of electrons and a wave function 104 of holes are separated when influenced by the internal electric field, so that the probability of combination is decreased (see FIG. 13(a)). This also affects each shape of a conduction band 101 and a valence band 102.

On the other hand, according to an active layer grown on a nonpolar plane such as an m-plane, the internal electric field is not generated in the active layer. Thus, as shown in FIG. 13(b), an overlapping portion between the wave function 103 of electrons and the wave function 104 of holes is large as compared with FIG. 13(a), and a high recombination probability is shown as compared with during c-plane growth.

FIG. 14 is a graph showing a relationship between a tilt angle and a magnitude of the internal electric field in an active layer when a growth plane during epitaxial growth is tilted from the c-plane. An angle of the growth plane to the c-plane is synonymous with an angle in a growth direction to the c-axis. The active layer is made of Al_{0.8}Ga_{0.2}N/AlN. A positive or negative sign showing a value of the internal electric field represented by the vertical axis shows the direction of the internal electric field.

According to FIG. 14, the internal electric field in the active layer during (0001) plane (c-plane) growth is largest, and as the growth plane is titled from the c-plane, the magnitude of the internal electric field is gradually reduced. The internal electric field becomes 0 when the growth plane is titled to a certain angle, and if the growth plane is further titled, the internal electric field whose direction is reversed as compared with during c-plane growth starts to be generated. If the tilt angle is further increased, the magnitude of the internal electric field increases to a certain tilt angle and then starts to be reduced. When the growth plane is tilted by 90° relative to the c-plane, that is, when a {10-10} plane (m-plane) is grown, the internal electric field in the active layer becomes 0.

As described above, since the recombination probability between electrons and holes is decreased due to the internal electric field generated in the active layer during c-plane growth, if the active layer can be grown with a plane tilted from the c-plane serving as a growth plane, the recombination probability can be improved while decreasing the internal electric field.

In Patent Document 1, after GaN is grown on an upper layer of a c-plane of a growth substrate, GaN is further epitaxially grown in such a state that a mask made of oxide silicon or nitride silicon is formed at a predetermined position on the GaN. Patent Document 1 describes that the above-described GaN layer having a side facet is accordingly formed.

At present, there has been developed a technique in which a nitride semiconductor such as GaN is epitaxially grown on a plane (such as the above-described m-plane) other than a c-plane of a growth substrate. However, as compared with the case where the nitride semiconductor is grown on the c-plane of the growth substrate, there are problems that a dislocation density is high, and morphology of a crystal surface is degraded, and this technique is still insufficient to form a semiconductor layer having a good crystal quality. Thus, also in Patent Document 1, the GaN layer is grown on the c-plane of the growth substrate, and after the GaN layer having a growth surface other than the c-plane is formed on an upper layer of the GaN layer, an active layer is grown on this growth surface. It is considered that this aims to achieve a semiconductor light emitting element which has an active layer having reduced influence of the internal electric field while ensuring a crystal quality during c-plane growth.

In Patent Document 1, examples of a material regrown after mask formation include GaN. An absorption edge of GaN is about 366 nm. Thus, when a semiconductor light emitting element which emits light having a wavelength less than 366 nm (for example, ultraviolet light) is to be achieved by the method described in Patent Document 1, ultraviolet light emitted from the active layer is absorbed by GaN, so that light extraction efficiency is extremely lowered.

AlN has been known as a nitride semiconductor having an absorption edge on the shorter wavelength side than in GaN. The absorption edge of AlN is about 200 nm. For AlGaN which is a ternary mixed crystal or AlInGaN with a low In composition ratio, its absorption edge is located between GaN and AlN in response to a ratio of Al and Ga. Thus, when epitaxial growth is performed by the method described in Patent Document 1 with the use of AlN or AlGaN, if a nonpolar plane or a semipolar plane is allowed to serve as a growth plane, since an active layer can be formed on such a plane, it is considered that an ultraviolet light emitting element with high light emitting efficiency can be achieved.

However, as a result of intensive studies made by the present inventors, when AlN or AlGaN is used instead of GaN, a plane other than a c-plane cannot serve as a growth plane even if the method described in Patent Document 1 is used. The reason thereof is considered by the inventors as follows.

In the method described in Patent Document 1, GaN is epitaxially grown in such a state that a mask is formed in a predetermined region of an upper surface. This is intended to limit a region to which a raw material gas adheres by a mask to thereby limit a direction of epitaxial growth and thus to achieve a growth plane other than a c-plane.

When the above method is adopted, it is a prerequisite that growth due to adhesion of a raw material gas does not occur on a mask. That is, while growth is not performed on the mask, the raw material gas is caused to adhere onto an exposed surface not covered with the mask and is selectively grown, whereby a growth plane different from a c-plane can be achieved. Growth does not occur on the mask because a difference arises in reaction rate between a region where the mask is formed and a region where the mask is not formed.

Here, when a raw material gas of AlN or AlGaN is supplied instead of GaN, since reactivity of Al is high, in addition to a region where no mask is formed, crystal growth progresses also on an upper surface of the mask. Thus, a method as in Patent Document 1 of forming a growth plane other than a c-plane with the use of selective growth cannot be adopted.

As a method of enhancing the light emitting efficiency, separately from a method of forming an active layer on a plane other than a c-plane, there is a method of reducing a width of a light emitting layer of an active layer. FIG. 15 is a graph in which a magnitude of an overlap integral (hereinafter referred to as an “overlap integrated value”) between a wave function of electrons and a wave function of holes is prescribed by a relationship with a width of a light emitting layer constituting an active layer. The active layer has a multi-cycle structure of a light emitting layer made of Al_{0.8}Ga_{0.2}N and a barrier layer made of AlN, and the horizontal axis corresponds to a film thickness of an Al_{0.8}Ga_{0.2}N layer. The recombination probability between electrons and holes is proportional to the magnitude of the overlap integral between the wave function of electrons and the wave function of holes.

According to FIG. 15, when no internal electric field exists in an active layer, a high overlap integrated value is exhibited regardless of a width of a light emitting layer. On the other hand, when an internal electric field exists in the active layer, in a region where the width of the light emitting layer is small, the overlap integrated value is as high as that of the case with no internal electric field; however, if the width of the light emitting layer is approximately 2.5 nm, an overlap integrated value approximately half that in the case where there is no internal electric field is exhibited. If the width of the light emitting layer is more than 2.5 nm, the overlap integrated value is further reduced.

As described above with reference to FIGS. 13(a) and 13(b), according to the internal electric field, a force acts in a direction in which the wave function of electrons and the wave function of holes are separated. Accordingly, when a width of Al_{0.8}Ga_{0.2}N constituting a light emitting layer, that is, the film thickness is reduced to reduce room for separation of the two wave functions, a degree of a decrease of the recombination probability can be suppressed.

In an LED, there has been known a phenomenon (droop phenomenon) in which the higher the current density, the lower the light emitting efficiency, and this phenomenon is an obstacle when a high output device is realized. There are a variety of discussions over the cause of this phenomenon, and although the cause cannot be specified at present, it is known that development of the droop phenomenon is suppressed by reducing a carrier density in a light emitting layer.

Here, if the width (film thickness) of the light emitting layer is increased, since a region where a carrier can be injected into the light emitting layer is enlarged, the carrier density can be reduced, and the effect of suppressing the droop phenomenon is expected. However, as described above, when the internal electric field exists in an active layer, if the width of the light emitting layer is increased, there is a problem that the recombination probability between electrons and holes is decreased to reduce the light emitting efficiency.

In view of the above problems, an object of the present invention is to achieve a semiconductor light emitting element which includes an Al-containing nitride semiconductor and has an active layer having a plane, other than a c-plane, as a growth surface; and a method for manufacturing the semiconductor light emitting element. Further, another object of the present invention is to achieve an LED element and an electron-beam-pumped light source device including the semiconductor light emitting element.

### Means for Solving the Problem

A method for producing a semiconductor light emitting element according to the present invention includes:

a step (a) of preparing a growth substrate;

a step (b) of growing a first layer made of Alₓ₁Ga_{y1}In_{1-x1-y1}N (0<x1≦1, 0≦y1≦1) on an upper layer of the growth substrate in a <0001> direction;

a step (c) of forming a groove portion extending along a <11-20> direction of the first layer with respect to the first layer with such a depth that a surface of the growth substrate is not exposed;

after the step (c), a step (d) of growing a second layer, which is made of Alₓ₂Ga_{y2}In_{1-x2-y2}N (0<x2≦1, 0≦y2≦1), on an upper layer of the first layer with at least a {1-101} plane serving as a crystal growth plane; and a step (e) of growing an active layer on an upper layer of the second layer.

As used herein, the {1-101} plane is a concept including a (1-101) plane and planes crystallographically equivalent to the (1-101) plane, that is, a (10-11) plane, a (01-11) plane, a (0-111) plane, a (−1101) plane, and a (−1011) plane. Further, as used herein, the <11-20> direction is a concept including a [11-20] direction and directions crystallographically equivalent to the [11-20] direction, that is, a [1-210] direction, a [−2110] direction, a [−1-120] direction, a [−12-10] direction, and a [2-1-10] direction.

As a result of intensive studies made by the present inventors, it has been found that when the second layer is crystal-grown after execution of the steps (a) to (c), at least the {1-101} plane can be crystal-grown as a crystal growth plane on the upper layer of the first layer grown in the <0001> direction, the contents of which will be described later in the section “Mode for Carrying Out the Invention”.

According to the above method, a crystal is grown on the upper layer of the first layer made of Alₓ₁Ga_{y1}In_{1-x1-y1}N (0<x1≦1, 0≦y1≦1) grown in the <0001> direction, whereby the second layer having the {1-101} plane as a crystal growth plane can be grown. Thus, when an active layer is grown on this plane, a semiconductor light emitting element having an active layer grown on a plane other than a c-plane can be achieved while ensuring a high crystal quality during c-plane growth. Consequently, a semiconductor light emitting element in which the internal electric field is suppressed can be achieved regardless of a width of a light emitting layer.

Here, the step (d) may be a step of growing the second layer on an upper side of a region where the groove portion is formed and an upper side of a region where the groove is not formed with a slope to a principal surface of the growth substrate serving as a crystal growth plane.

According to the above method, as compared with a case where the second layer is grown from only above the region where the groove portion is not formed with the slope serving as a crystal growth plane, a pitch of concavoconvexes of the second layer can be narrowed. Consequently, light extraction efficiency can be enhanced. Moreover, since the second layer can be grown with the slope serving as a crystal growth plane even if the film thickness of the second layer is small, a growth time of the second layer can be reduced, and efficiency in manufacturing is enhanced.

As described above, one of the reasons why the second layer can be grown on not only the upper side of the region where the groove portion is not formed but also the upper side of the region where the groove portion is formed with the slope serving as a crystal growth plane is that the second layer contains Al. If the second layer is to be made of GaN, a mode of horizontal direction growth is apt to be expressed, so that before growth from the region where the groove portion is formed begins, growth from an inner side surface of the groove portion and an upper surface of a region where the groove portion is not formed is preferential. Due to this, it is difficult to grow GaN on the upper side of the region where the groove portion is formed with the slope serving as a crystal growth plane.

On the other hand, as described above, when the second layer is a nitride layer containing Al, since the horizontal direction growth mode can be made less likely to be expressed, a crystal is easily grown also on an upper surface of the region where the groove portion is formed. Due to this, the second layer can be grown on the upper side of the region where the groove portion is formed and the upper side of the region where the groove portion is not formed with the slope serving as a crystal growth plane.

Here, in the first layer, the Al ratio is not less than 50%, and namely, the first layer can be made of Alₓ₁Ga_{y1}In_{1-x1-y1}N (0.5≦x1≦1, 0≦y1≦1). Further, the first layer may be also made of AlN. According to these constitutions, a short-wavelength semiconductor light emitting element with high light emitting efficiency is achieved.

In the first layer and the second layer, In composition may be not more than 1%.

The second layer may be made of AlN or Alₓ₂Ga₁₋ₓ₂N (0<x2≦1).

In the above method, after execution of the step (d), the crystal growth plane of the second layer may include a {1-101} plane and a {0001} plane.

Further, in the above method, after execution of the step (d), the crystal growth plane of the second layer may only include a {1-101} plane.

According to intensive studies made by the present inventors, it has been found that a ratio at which the {0001} plane is allowed to appear as a growth plane of the second layer can be controlled by adjusting the width (length in a direction parallel to the surface of the growth substrate) and depth (length in a direction orthogonal to the surface of the growth substrate) of the groove portion formed in the step (c) and an interval from an adjacent groove portion. More specifically, the ratio at which the {0001} plane is allowed to appear can be reduced by reducing the width of the groove portion and an interval between adjacent groove portions and increasing the depth.

Thus, as the growth plane of the second layer, only the {1-101} plane may be used without having the whole {0001} plane, and when an active layer is formed on the upper layer of the second layer, a semiconductor light emitting element in which there is no or almost no internal electric field can be achieved.

According to the above method, a semiconductor light emitting element having both the active layer formed on the {0001} plane and the active layer formed on the {1-101} plane is achieved. In these active layers, light beams having different wavelengths can be emitted from the active layers according to a difference in growth conditions and the magnitude of the internal electric field. Thus, according to this method, a light emitting element having a plurality of peak wavelengths can be achieved.

The step (c) may be a step of forming the groove portion extending in two or more different directions belonging to the <11-20> direction.

A semiconductor light emitting element according to the present invention has:

a first layer made of Alₓ₁Ga_{y1}In_{1-x1-y1}N (0<x1≦1, 0≦y1≦1) with a {0001} plane serving as a crystal plane;

a second layer formed on an upper layer of the first layer and made of Alₓ₂Ga_{y2}In_{1-x2-y2}N (0<x2≦1, 0≦y2≦1); and

an active layer formed on an upper layer of the second layer, and

in this semiconductor light emitting element, the first layer has a recess extending along a <11-20> direction on a surface on the second layer side, and

at least a portion of the active layer is formed on a {1-101} plane of the second layer.

According to the above semiconductor light emitting element, a semiconductor light emitting element as a short-wavelength light source with high light emitting efficiency can be achieved regardless of a width of a light emitting layer.

The second layer may include a slope to a principal surface of the growth substrate on an upper side of a region where the recess is formed and on an upper side of a region where the recess is not formed, both of which being upper layers of the first layer.

In addition to the above constitution, the first layer may be made of Alₓ₁Ga_{y1}In_{1-x1-y1}N (0.5≦x1≦1, 0≦y1≦1). Further, the first layer may be made of AlN.

In addition to the above constitution, the second layer may be made of AlN. Further, the second layer may be made of Alₓ₂Ga₁₋ₓ₂N.

In addition to the above constitution, the active layer may be formed on the {1-101} plane of the second layer and the {0001} plane of the second layer. According to this configuration, a short-wavelength light emitting element with high light emitting efficiency and having a plurality of peak wavelengths can be achieved.

The active layer may be formed only on the {1-101} plane of the second layer. According to this configuration, a short-wavelength light emitting element with extremely high light emitting efficiency can be achieved.

An electron-beam-pumped light source device according to the present invention includes:

a semiconductor light emitting element having any of the above characteristics and an electron beam source, and

in this electron-beam-pumped light source device, the active layer emits light when an electron beam emitted from the electron beam source enters the active layer.

An LED element according to the present invention includes:

a semiconductor light emitting element having any of the above characteristics;

a third layer provided on an upper layer of the active layer and made of Alₓ₄Ga_{y4}In_{1-x4-y4}N (0<x4≦1, 0≦y4≦1) of any one of an n-type conduction type and a p-type conduction type;

a first electrode electrically connected to the second layer; and

a second electrode electrically connected to the third layer, and

in this LED element, the second layer is made of Alₓ₂Ga_{y2}In_{1-x2-y2}N of a conduction type different from that in the third layer.

More specifically, the second layer may be of the n-type, and the third layer may be of the p-type. In this case, the first electrode constitutes an “n-side electrode”, and the second electrode constitutes a “p-side electrode”.

### Effect of the Invention

The present invention achieves a short-wavelength semiconductor light emitting element with high light emitting efficiency and an LED element and an electron-beam-pumped light source device including the semiconductor light emitting element.

### BRIEF DESCRIPTION OF THE DRAWINGS

FIG. 1 is a cross-sectional view schematically showing a structure of a semiconductor light emitting element according to a first embodiment.

FIGS. 2(a) and 2(b) are views schematically showing a structure of an electron-beam-pumped light source device including the semiconductor light emitting element.

FIG. 3 is a schematic enlarged view of an electron beam source.

FIG. 4A is a cross-sectional view in one step in a method for manufacturing the semiconductor light emitting element according to the first embodiment.

FIG. 4B is a cross-sectional view in one step in the method for manufacturing the semiconductor light emitting element according to the first embodiment.

FIG. 4C is a cross-sectional view in one step in the method for manufacturing the semiconductor light emitting element according to the first embodiment.

FIG. 4D is a cross-sectional view in one step in the method for manufacturing the semiconductor light emitting element according to the first embodiment.

FIGS. 5A(a) and 5A(b) are SEM photographs of an element of Example 1.

FIGS. 5B(a) and 5B(b) are SEM photographs of an element of Example 2.

FIGS. 5C(a) and 5C(b) are SEM photographs of an element of Comparative Example 1.

FIG. 6 is a SEM photograph of each element of Example 3 and Comparative Example 2.

FIG. 7 is a SEM photograph of each element of Example 4 and Example 5.

FIG. 8A is a cross-sectional view in one step in the method for manufacturing the semiconductor light emitting element according to the first embodiment.

FIG. 8B is a cross-sectional view schematically showing another structure of the semiconductor light emitting element according to the first embodiment.

FIG. 9 is a schematic cross-sectional view of the semiconductor light emitting element realized as an LED.

FIG. 10 is a top view in one step in a method for manufacturing a semiconductor light emitting element of another embodiment.

FIG. 11 is a view schematically showing a unit lattice of GaN crystal.

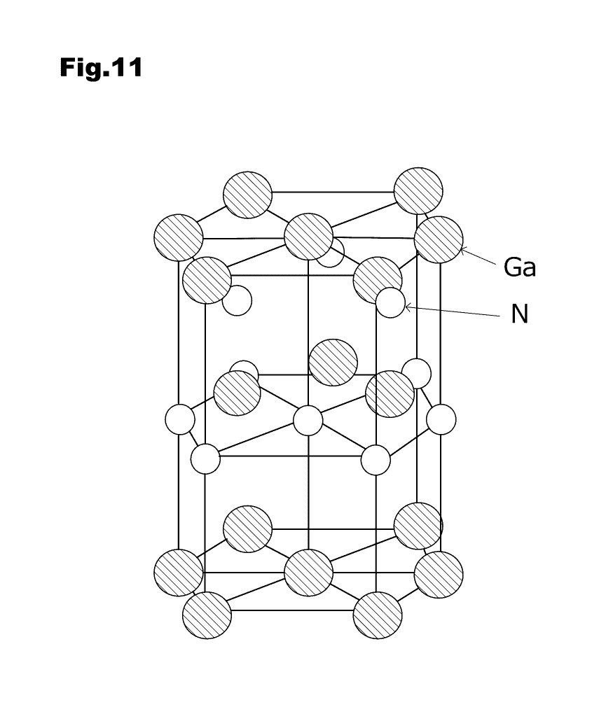

FIG. 12 is a view for explaining a plane direction of a wurtzite crystal structure.

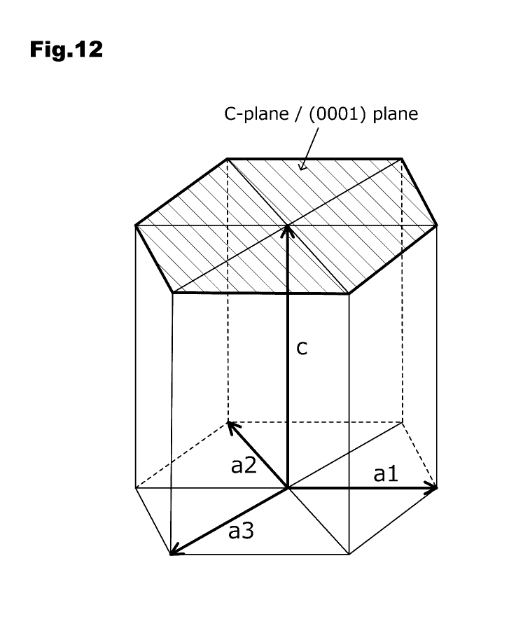

FIGS. 13(a) and 13(b) are views for explaining an influence of an internal electric field on an energy band of an active layer.

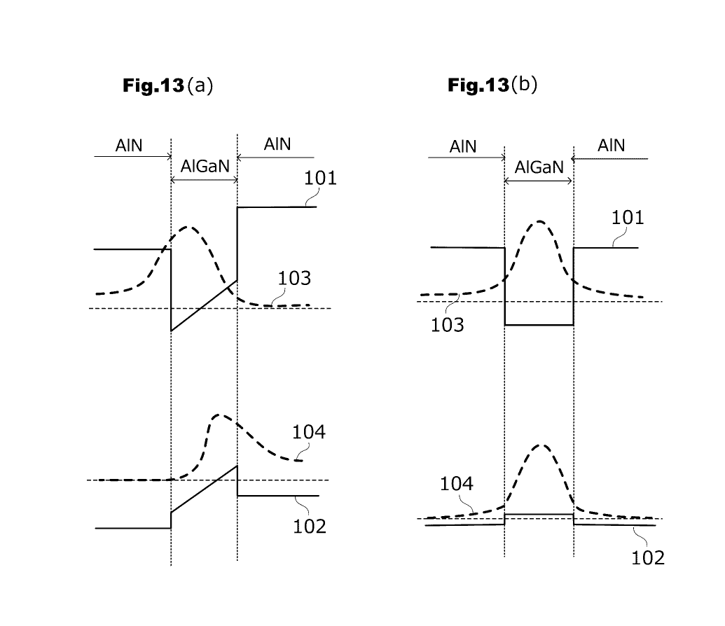

FIG. 14 is a graph showing a relationship between a tilt angle and a magnitude of the internal electric field when a growth plane during epitaxial growth is tilted from a c-plane.

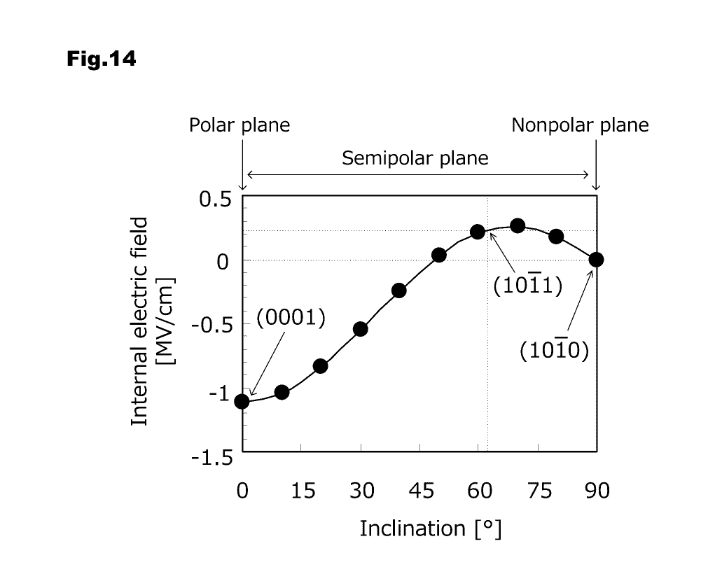

FIG. 15 is a graph in which a magnitude of an overlap integral between a wave function of electrons and a wave function of holes is prescribed by a relationship with a width of a light emitting layer.

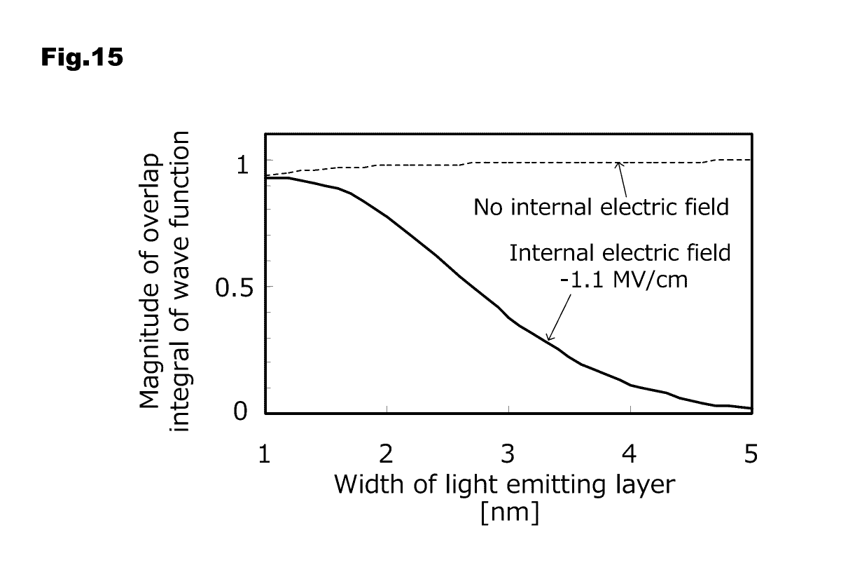

### MODE FOR CARRYING OUT THE INVENTION

### First Embodiment

A first embodiment of the present invention will be described.

(Structure of Semiconductor Light Emitting Element)

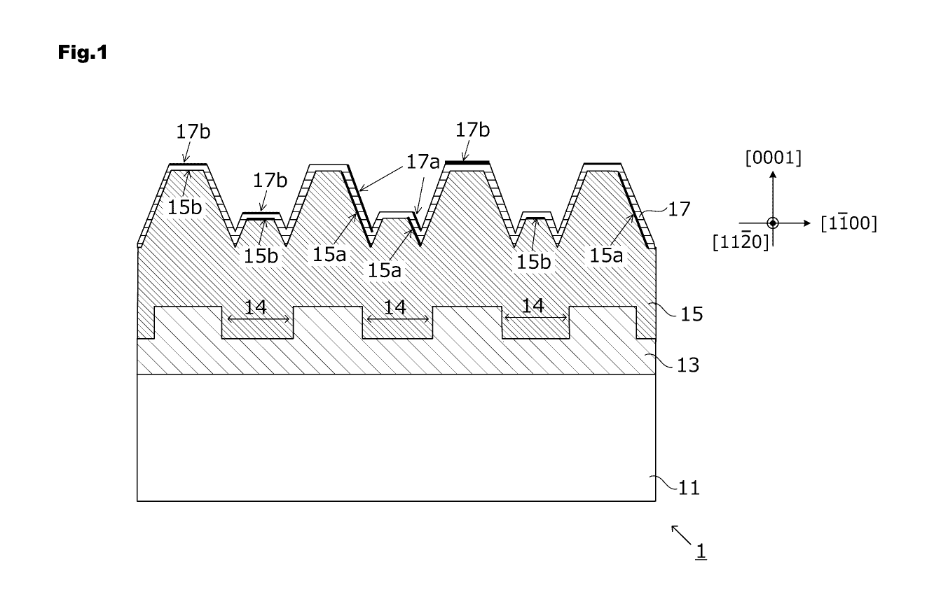

FIG. 1 is a view schematically showing a structure of a semiconductor light emitting element according to the first embodiment. A semiconductor light emitting element 1 includes a growth substrate 11, a first layer 13, a second layer 15, and an active layer 17. FIG. 1 corresponds to a cross-sectional view when the semiconductor light emitting element 1 is cut in a plane formed by a [0001] direction and a [1-100] direction. The depth direction in FIG. 1 is a [11-20] direction.

The growth substrate 11 is formed of, for example, a sapphire substrate, and a growth plane is a (0001) plane (c-plane). Note that SiC and the like can be used in addition to the sapphire substrate.

The first layer 13 is formed of an AlN layer in this embodiment. The first layer 13 can be formed of a nitride semiconductor layer specified by the general formula Alₓ₁Ga_{y1}In_{1-x1-y1}N (0<x1≦1, 0≦y1≦1) in addition to AlN. In this case, the In composition is preferably not more than 1%. The composition of Al is suitably selected according to the light emitting wavelength.

The first layer 13 has a recess 14 extending along a [11-20] direction. In this embodiment, although the extending direction of the recess 14 is the [11-20] direction, the extending direction may be a direction crystallographically equivalent to the [11-20] direction, that is, a <11-20> direction.

The second layer 15 is formed of an AlN layer in this embodiment. The second layer 15 can be formed of a nitride semiconductor layer specified by the general formula Alₓ₂Ga_{y2}In_{1-x2-y2}N (0<x2≦1, 0≦y2≦1) in addition to AlN. In this case, the In composition is preferably not more than 1%. The composition of Al is suitably selected according to the light emitting wavelength.

In this embodiment, the second layer 15 has a growth plane 15a parallel to a {1-101} plane and a growth plane 15b parallel to a {0001} plane. When the semiconductor light emitting element is manufactured by a manufacturing method to be described later, such a configuration is achieved.

In this embodiment, the active layer 17 is configured such that Alₓ₃Ga₁₋ₓ₃N (0<x3≦1)/AlN is stacked in one or multiple cycles. As one example, the active layer 17 is configured such that light emitting layers each made of Al_{0.8}Ga_{0.2}N and barrier layers each made of AlN are repeated in multiple cycles. The configuration of the active layer 17 is suitably selected according to the light emitting wavelength.

In this embodiment, the active layer 17 has a growth plane 17a parallel to the {1-101} plane and a growth plane 17b parallel to the {0001} plane, as in the second layer 15.

In the configuration of this embodiment disclosed in FIG. 1, the second layer 15 has, in the upper layer of the first layer 13, the growth plane 15a parallel to the {1-101} plane both on the upper side of a region where the recess 14 is formed and on the upper side of a region where the recess 14 is not formed. However, the second layer 15 of the semiconductor light emitting element 1 is not limited to this configuration. Also, the active layer 17 has, in the upper layer of the second layer 15, the growth plane 17a parallel to the {1-101} plane both on the upper side of the region where the recess 14 is formed and on the upper side of the region where the recess 14 is not formed. However, the active layer 17 is not limited to this configuration.

(Configuration of Electron-Beam-Pumped Light Source Device)

Next, a case where the semiconductor light emitting element 1 shown in FIG. 1 is used in an electron-beam-pumped light source device will be described.

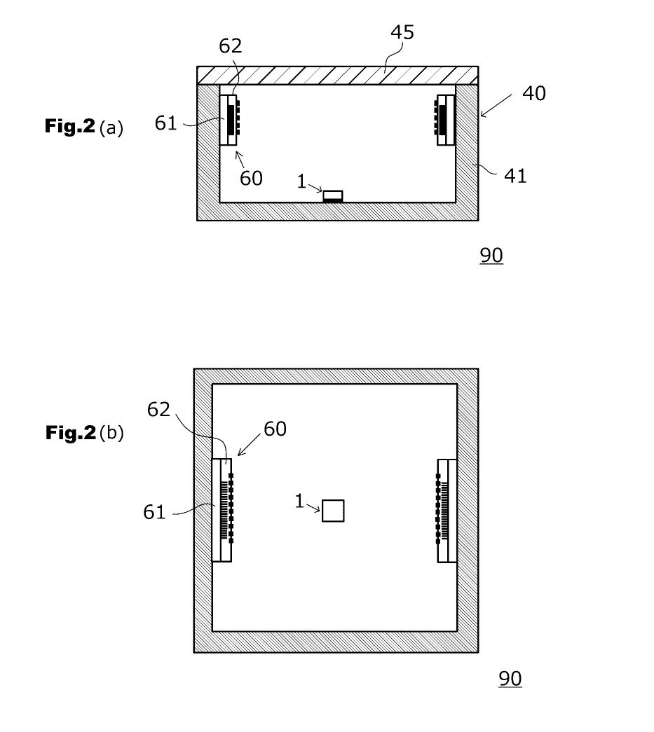

FIGS. 2(a) and 2(b) are views schematically showing a configuration of an electron-beam-pumped light source device including the semiconductor light emitting element 1 shown in FIG. 1. FIG. 2(a) is a side cross-sectional view, and FIG. 2(b) is a top planar view. FIG. 2(b) shows a state in which a light transmission window 45 to be described later is removed.

An electron-beam-pumped light source device 90 has a vacuum vessel 40 which is sealed to have a negative internal pressure and has a rectangular parallelepiped outer shape. The vacuum vessel 40 is constituted of a vessel housing 41, which has an opening on one surface, and the light transmission window 45 which is disposed at the opening of the vessel housing 41 and hermetically sealed to the vessel housing 41.

As shown in FIGS. 2(a) and 2(b), the semiconductor light emitting element 1 shown in FIG. 1 is disposed on an inner surface of a bottom wall of the vessel housing 41 such that a side opposite to the growth substrate 11, that is, the active layer 17 side constituting a light extraction surface is spaced apart from and faces the light transmission window 45. In a peripheral region of the semiconductor light emitting element 1, a plurality of (two, in the illustrated example) electron beam sources 60 each formed by providing a rectangular planer electron beam emitting portion 62 on a rectangular support substrate 61 are arranged at positions where the semiconductor light emitting element 1 is held in between.

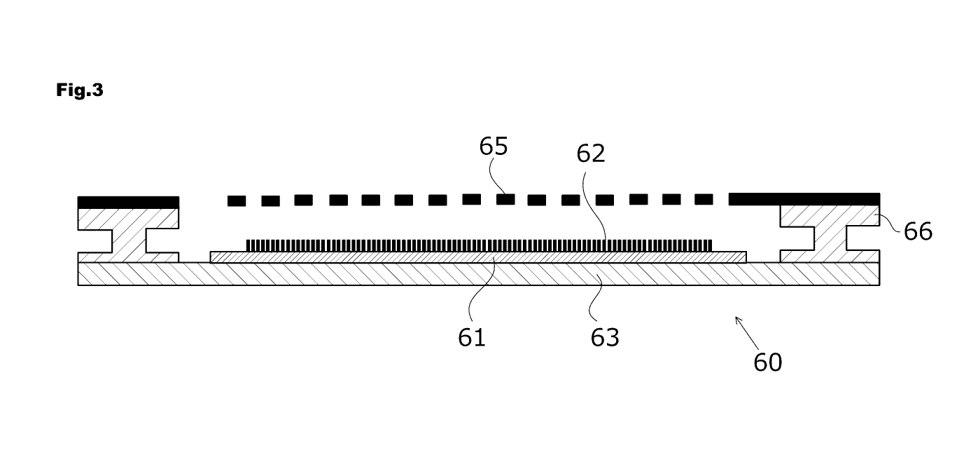

FIG. 3 is a schematic enlarged view of the electron beam source 60. The electron beam emitting portion 62 is formed such that many carbon nanotubes are supported on the support substrate 61, and the support substrate 61 is fixed onto a plate-like base portion 63. A net-like extraction electrode 65 is disposed above the electron beam emitting portion 62 so as to be spaced apart from and face the electron beam emitting portion 62, and the extraction electrode 65 is fixed to the base portion 63 through an electrode holding member 66. The support substrate 61 and the extraction electrode 65 are electrically connected to a power supply for electron beam emission (not shown), which is provided outside the vacuum vessel 40, through a conductive wire (not shown) drawn from the inside of the vacuum vessel 40 to the outside.

In the configuration shown in FIGS. 2(a) and 2(b), the respective base portions 63 are fixed to inner surfaces of two side walls of the vessel housing 41 facing each other, whereby the electron beam sources 60 are arranged such that the electron beam emitting portions 62 face each other at the positions where the semiconductor light emitting element 1 is held in between.

In the electron-beam-pumped light source device 90, when a voltage is applied to between the electron beam source 60 and the extraction electrode 65, electrons are emitted from the electron beam emitting portion 62 toward the extraction electrode 65, and the electrons travel toward the semiconductor light emitting element 1 while being accelerated by an acceleration voltage applied to between the semiconductor light emitting element 1 and the electron beam source 60 and enter as an electron beam a surface of the active layer 17 of the semiconductor light emitting element 1. According to this configuration, the electrons of the active layer 17 are excited, and light such as ultraviolet light is emitted from the surface where the electron beam has entered and is emitted outward from the vacuum vessel 40 through the light transmission window 45.

According to this configuration, since the active layer 17 has the growth plane 17a parallel to the {1-101} plane, influence of an internal electric field is suppressed, and an electron-beam-pumped light source device with high light emitting efficiency is achieved. Moreover, in this embodiment, since the active layer 17 has the growth plane 17b parallel to the {0001} plane in addition to the growth plane 17a parallel to the {1-101} plane, there is an effect that a plurality of light beams having different peak wavelengths can be emitted.

(Production Method)

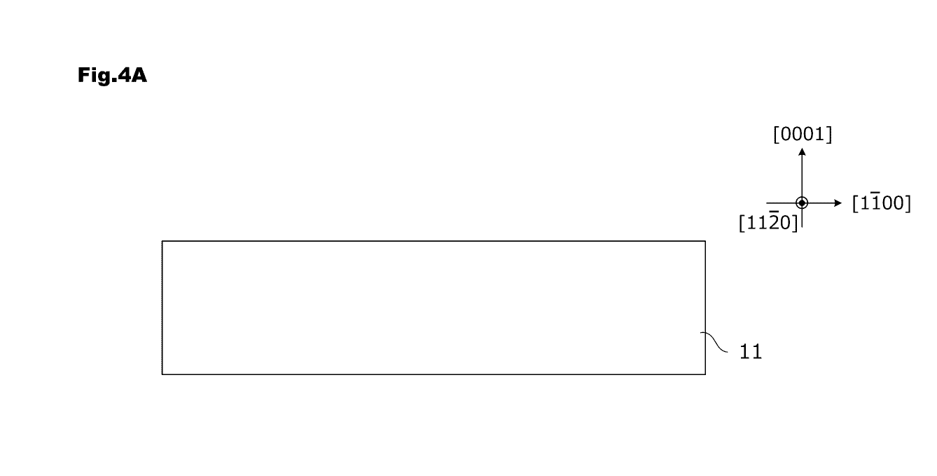

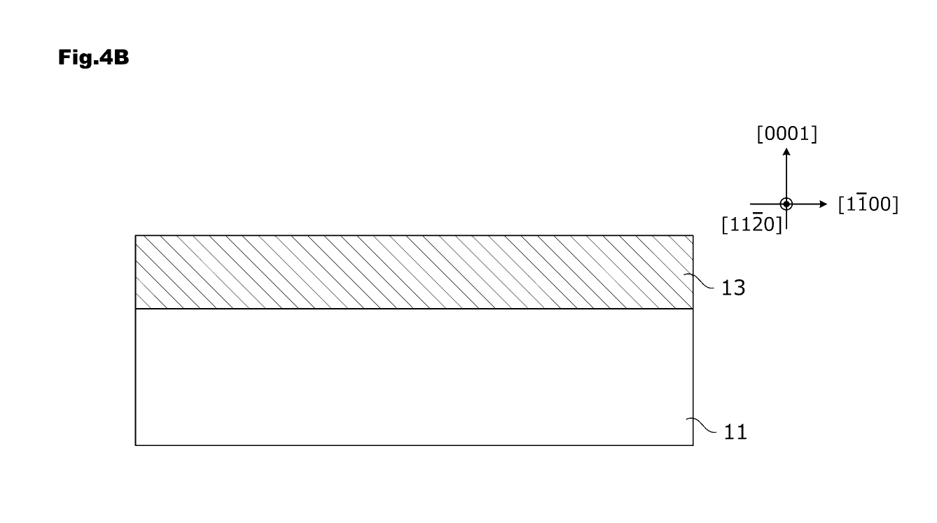

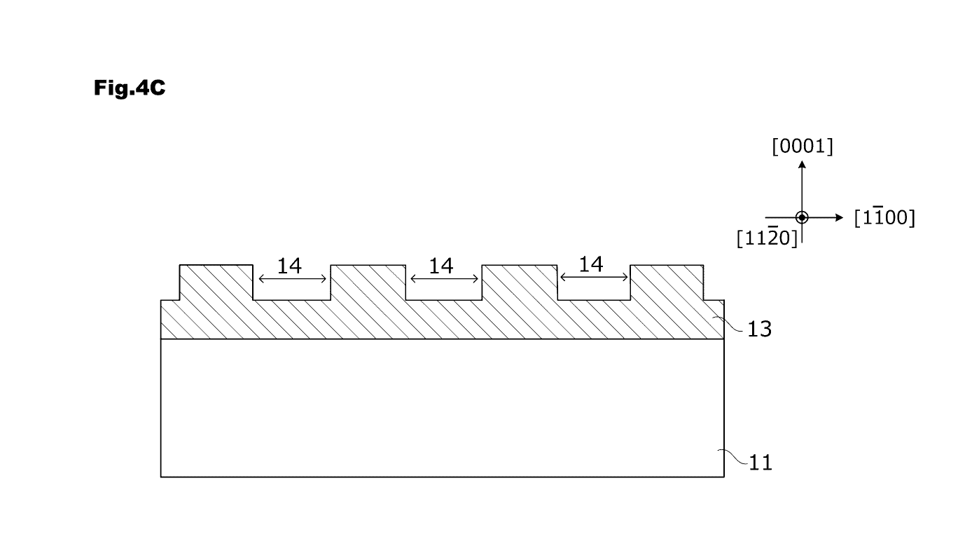

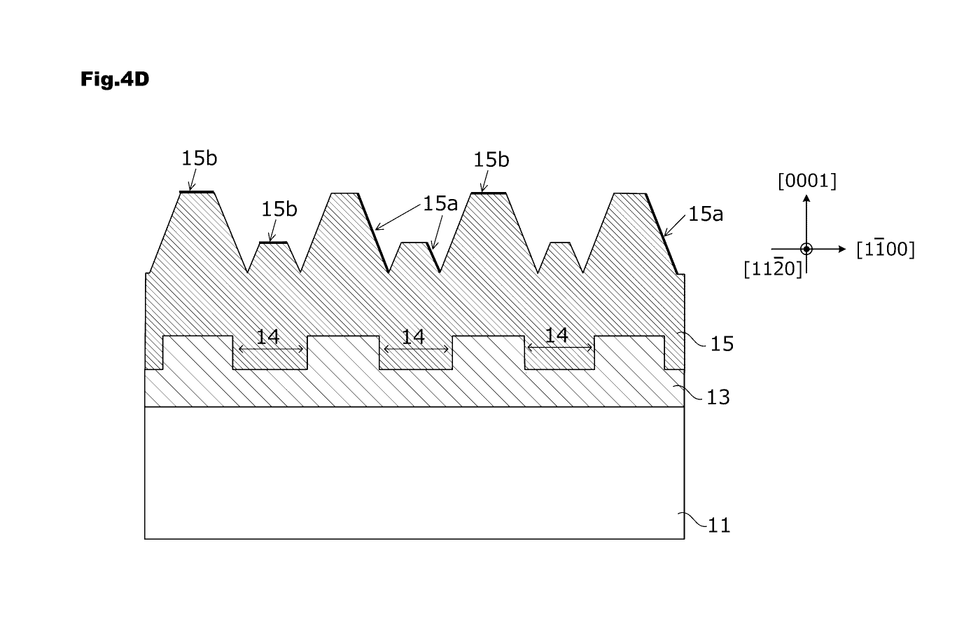

A method for producing the semiconductor light emitting element 1 will be described with reference to the process cross-sectional views of FIGS. 4A to 4D. Each process cross-sectional view corresponds to a cross-sectional view obtained when the element at each time point is cut in a plane formed by the [0001] direction and the [1-100] direction, as in FIG. 1.

(Step S1)

The growth substrate 11 is prepared (see FIG. 4A). As the growth substrate 11, a sapphire substrate having a (0001) plane may be used as one example.

As a preparation process, the growth substrate 11 is cleaned. As a more specific example of the cleaning process, the growth substrate 11 is disposed in a treatment furnace of an MOCVD (Metal Organic Chemical Vapor Deposition) apparatus, and while hydrogen gas with a flow rate of 10 slm, for example, is flown inside the treatment furnace, an in-furnace temperature is increased to 1150° C., for example.

Step S1 corresponds to the step (a).

(Step S2)

As shown in FIG. 4B, the first layer 13 made of, for example, MN is formed on the (0001) plane of the growth substrate 11. As one example of a specific method, the in-furnace temperature of the MOCVD device is set to not less than 900° C. and not more than 1600° C., and while nitrogen gas and hydrogen gas as carrier gasses are flown, trimethylaluminum (TMA) and ammonia as raw material gasses are supplied into the treatment furnace. A flow rate ratio (V/III ratio) of TMA and ammonia is set to a value of not less than 10 and not more than 4000, a growth pressure is set to a value of not less than 10 torr and not more than 500 torr, and a supply time is suitably adjusted, whereby AlN having a desired film thickness is formed. In this case, the first layer 13 made of AlN having a film thickness of 600 nm was formed.

When Alₓ₁Ga_{y1}In_{1-x1-y1}N (0<x1≦1, 0≦y1≦1) is used as the first layer 13, trimethylgallium (TMG) and trimethylindium (TMI) may be supplied at a predetermined flow rate corresponding to the composition, in addition to TMA and ammonia.

As the thickness of the first layer 13, a sufficient thickness that can obtain good crystallinity may be set, and the thickness may be set to not less than 400 nm, for example.

Step S2 corresponds to the step (b).

(Step S3)

As shown in FIG. 4C, a groove portion (recess) 14 provided along the <11-20> direction is formed in the first layer 13. As one example of a specific method, a wafer obtained by executing Steps S1 to S2 is taken out from the treatment furnace, and a plurality of grooves parallel to the <11-20> direction of the first layer 13 are formed at predetermined intervals by a photolithography method and a reactive ion etching method (RIE method). In FIG. 4C, the groove portion 14 extends in the [11-20] direction which is a direction crystallographically equivalent to the <11-20> direction.

In Step S3, control is performed such that the groove portion 14 is formed with a depth in a range where the growth substrate 11 is not exposed from a bottom surface of the groove portion 14. It is preferable that the first layer 13 having a thickness of not less than 200 nm is formed between the bottom surface of the groove portion 14 and the growth substrate 11.

Step S3 corresponds to the step (c).

(Step S4)

As shown in FIG. 4D, the second layer 15 is formed on an upper surface of the first layer 13 having the groove portions 14 formed along the <11-20> direction. As one example of a specific method, the wafer obtained after completion of execution of Step S3 is put into the furnace of the MOCVD device again. The in-furnace temperature of the MOCVD device is set to not less than 900° C. and not more than 1600° C., and while nitrogen gas and hydrogen gas as carrier gasses are flown, TMA and ammonia as raw material gasses are supplied into the treatment furnace. The flow rate ratio (V/III ratio) of TMA and ammonia is set to a value of not less than 10 and not more than 4000, a growth pressure is set to a value of not less than 10 torr and not more than 500 torr, and a supply time is suitably adjusted, whereby AlN having a desired film thickness is formed. In this case, the second layer 15 made of AlN having a film thickness of 3000 nm was formed.

When Alₓ₂Ga_{y2}In_{1-x2-y2}N (0<x2≦1, 0≦y2≦1) is used as the second layer 15, TMG and TMI may be supplied at a predetermined flow rate corresponding to the composition, in addition to TMA and ammonia.

When a crystal is grown on the first layer 13 formed with the groove portion 14 having such a depth that an upper surface of the growth substrate 11 is not exposed, the second layer 15 having the growth plane 15a parallel to the {1-101} plane and the growth plane 15b parallel to the {0001} plane can be formed. Hereinafter, this point will be described with reference to Examples and Comparative Examples.

<Verification 1>

First, a preferable depth of the groove portion 14 will be verified with reference to the following Example 1, Example 2, and Comparative Example 1.

### Example 1

After a first layer 13 made of AlN having a film thickness of 600 nm was grown on a growth substrate 11 formed of a c-plane sapphire substrate in a [0001] direction, a groove portion 14 having a depth of 300 nm was formed along a [11-20] direction, and a second layer 15 made of AlN was grown thereon, whereby an element of Example 1 was produced. In the element of Example 1, since the depth of the groove portion 14 is smaller than the film thickness of the first layer 13, a surface of the growth substrate 11 is not exposed even when the groove portion 14 is formed.

### Example 2

An element of Example 2 was produced in the same manner as in Example 1, except that the depth of the groove portion 14 was 400 nm In the element of Example 2, as in the element of Example 1, since the depth of the groove portion 14 is smaller than the film thickness of the first layer 13, the surface of the growth substrate 11 is not exposed in the state in which the groove portion 14 is formed.

### Comparative Example 1

An element of Comparative Example 1 was produced in the same manner as in Example 1, except that the depth of the groove portion 14 was 600 nm. That is, in the element of Comparative Example 1, after the groove portion 14 is formed such that an upper surface of the growth substrate 11 exposed, the second layer 15 is grown.

(Result Analysis)

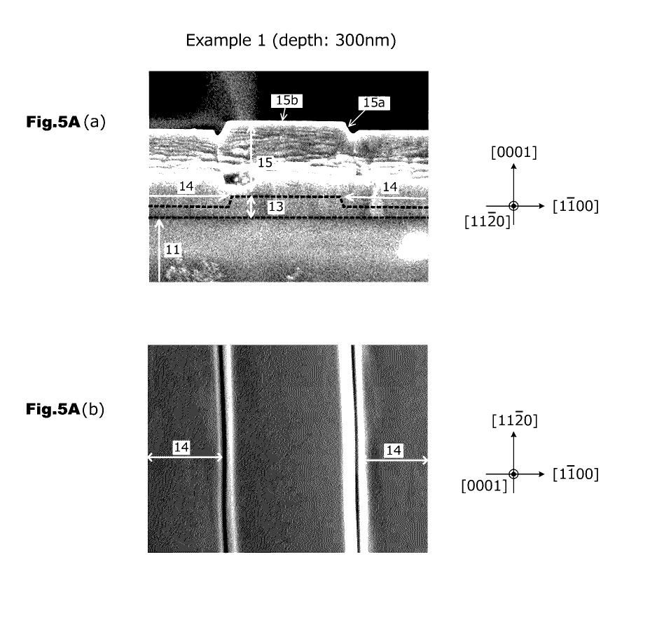

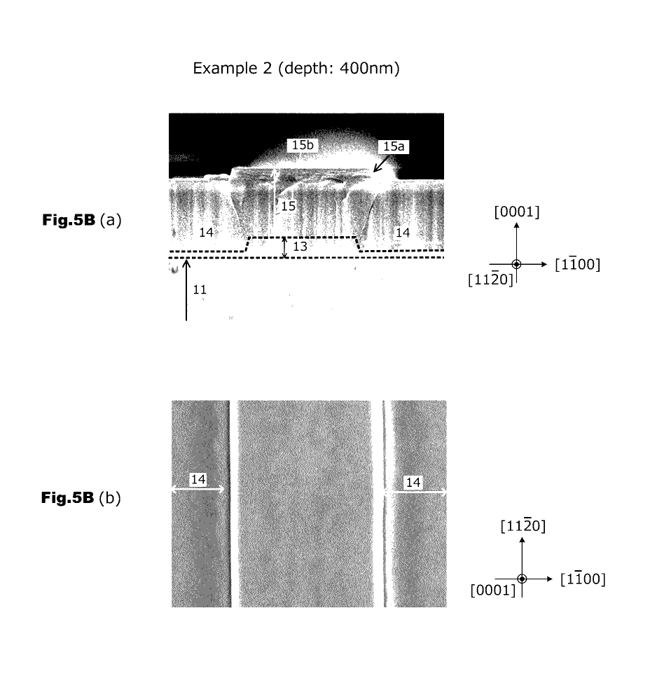

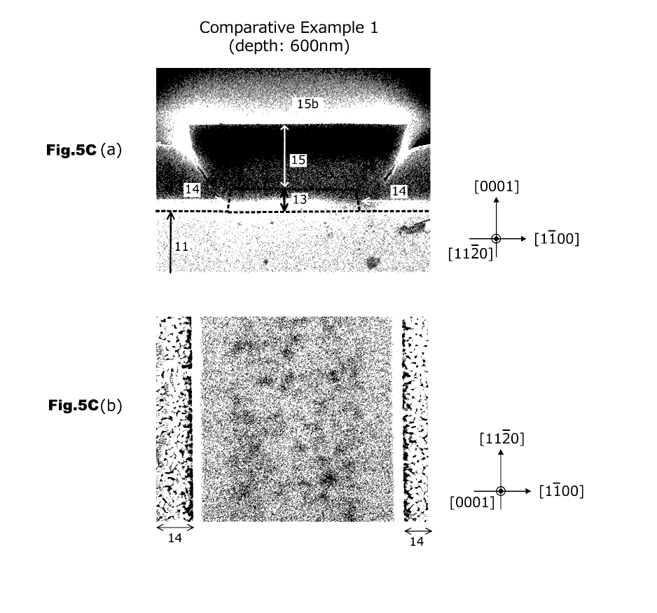

FIGS. 5A(a) and 5(b) are SEM (Scanning Electron Microscope) photographs of the element of Example 1. FIGS. 5B(a) and 5B(b) are SEM photographs of Example 2. FIGS. 5C(a) and 5C(b) are SEM photographs of Comparative Example 1. In each of FIGS. 5A(a) to 5C(b), (a) is a cross-sectional SEM photograph taken when each element is cut in a plane formed by the [0001] direction and the [1-100] direction, (b) is a SEM photograph obtained by photographing each element from an upper surface, that is, a plane formed by the [11-20] direction and the [1-100] direction.

According to FIGS. 5A(a) and 5A(b), in the element of Example 1, it is confirmed that the second layer 15 is formed to have a growth plane 15a parallel to a [1-101] plane and a growth plane 15b parallel to a [0001] plane. According to FIGS. 5B(a) and 5B(b), also in the element of Example 2, it is confirmed that the second layer 15 is formed to have the growth plane 15a parallel to the [1-101] plane and the growth plane 15b parallel to the [0001] plane.

On the other hand, according to FIGS. 5C(a) and 5C(b), in the second layer 15 of the element of Comparative Example 1, the growth plane 15a parallel to the [1-101] plane cannot be confirmed, and only the growth plane 15b parallel to the [0001] plane is confirmed. Further, it is confirmed that along the [0001] direction, the element of Comparative Example 1 is formed to be wider in a direction parallel to the plane formed by the [11-20] direction and the [1-100] direction. This suggests that a growth mode of the second layer 15 is a horizontal direction (plane direction) growth mode. If such a growth mode is expressed, the growth plane 15a parallel to the [1-101] plane is not allowed to appear.

The above configuration suggests that, in the formation of the groove portion 14 in Step S3, when the groove portion 14 is formed such that the depth of the groove portion 14 is smaller than the film thickness of the first layer 13 and the surface of the growth substrate 11 is not exposed, the second layer 15 is formed in a state of having a growth plane other than the [0001] plane.

As a reason for this, it is considered that when the second layer 15 (AlN, in this embodiment) is grown in such a state that the surface of the growth substrate 11 (that is, sapphire) is exposed, as in the element of Comparative Example 1, the growth mode is a mode in which a stable plane is less likely to be formed due to a change in a reaction state, as compared with the case where the second layer 15 is grown in such a state that the surface of the growth substrate 11 is not exposed as in the elements of Examples 1 and 2.

With reference to FIGS. 5A(b), 5B(b), and 5C(b), in the element of Comparative Example 1, it is confirmed that a surface state in the groove portion (recess) 14 is rough. As a reason for this, it is inferable that in the element of Comparative Example 1, since the growth substrate 11 (sapphire) is exposed in the groove portion 14, AlN cannot be epitaxially grown and exists in a polycrystal state in such a region.

<Verification 2>

Next, a preferable direction in which the groove portion 14 extends will be verified with reference to the following Example 3 and Comparative Example 2.

### Example 3

After a first layer 13 made of AlN having a film thickness of 1000 nm was grown on a growth substrate 11 formed of a c-plane sapphire substrate in a [0001] direction, a groove portion 14 having a depth of 500 nm was formed along a [11-20] direction, and a second layer 15 made of AlN was grown thereon, whereby an element of Example 3 was produced. In the element of Example 3, since the depth of the groove portion 14 is smaller than the film thickness of the first layer 13, as in each of the elements of Examples 1 and 2, a surface of the growth substrate 11 is not exposed even when the groove portion 14 is formed.

### Comparative Example 2

An element of Comparative Example 2 was produced in the same manner as in Example 3, except that the direction of the groove portion 14 is the [1-100] direction rotated by 90° from the element of Example 2. Also in the element of Comparative Example 2, as in the element of Example 3, since the depth of the groove portion 14 is smaller than the film thickness of the first layer 13, the surface of the growth substrate 11 is not exposed even when the groove portion 14 is formed.

(Result Analysis)

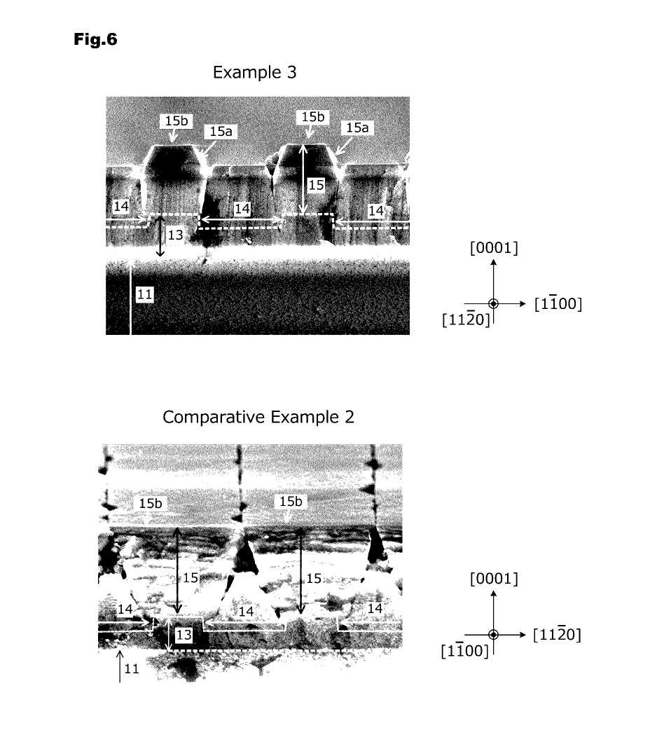

FIG. 6 is a SEM photograph of each of the elements of Example 3 and Comparative Example 2 and, as in FIG. 5A(a), is a cross-sectional SEM photograph taken when each element is cut in a plane formed by the [0001] direction and the [1-100] direction.

According to FIG. 6, in the element of Example 3, it is confirmed that the second layer 15 is formed to have a growth plane 15a parallel to a [1-101] plane and a growth plane 15b parallel to a [0001] plane.

On the other hand, in the element of Comparative Example 2, in the second layer 15, only the growth plane 15b parallel to the [0001] plane is confirmed. Also in the element of Comparative Example 2, as in the element of Comparative Example 1, it is confirmed that along the [0001] direction, the element of Comparative Example 2 is formed to be wider in a direction parallel to the plane formed by the [11-20] direction and the [1-100] direction. This suggests that a growth mode of the second layer 15 is a horizontal direction (plane direction) growth mode. If such a growth mode is expressed, a growth plane nonparallel to the [0001] plane is not allowed to appear.

When the groove portion 14 extending in the [11-20] direction is formed to grow the second layer 15 as in the element of Example 3, the growth plane 15a parallel to the [1-101] plane is obtained. In view of the above fact, it is considered that when the second layer 15 is grown such that the groove portion 14 extending in the [1-100] direction is formed as in the element of Comparative Example 2, for example, a [11-22] plane is obtained as a growth plane. However, in the element of Comparative Example 2, such a growth plane nonparallel to the [0001] plane is not confirmed.

From the above result, in order to obtain a growth plane nonparallel to the plane when the second layer 15 is grown, it is considered that the extending direction of the groove portion 14 is required to be the [11-20] direction and a direction crystallographically equivalent to this direction, due to a relationship with a crystal.

<Verification 3>

A relationship between a width of the groove portion 14 (length in the [1-100] direction) and a depth of the groove portion 14 (length in the [0001] direction) will be verified.

### Example 4

After a first layer 13 made of AlN having a film thickness of 600 nm was grown on a growth substrate 11 formed of a c-plane sapphire substrate in a [0001] direction, a plurality of groove portions 14 having a depth of 400 nm and a width of 5 μm were formed along a [11-20] direction in intervals of 5 μm, and a second layer 15 made of AlN was grown thereon, whereby an element of Example 4 was produced. In the element of Example 4, since the depth of the groove portion 14 is smaller than the film thickness of the first layer 13, a surface of the growth substrate 11 is not exposed even when the groove portion 14 is formed.

### Example 5

An element of Example 5 was produced in the same manner as in Example 4, except that a plurality of groove portions 14 having a depth of 500 nm and a width of 2 μm were formed in intervals of 2 μm. In the element of Example 5, as in the element of Example 4, since the depth of the groove portion 14 is smaller than the film thickness of the first layer 13, a surface of a growth substrate 11 is not exposed even when the groove portion 14 is formed.

(Result Analysis)

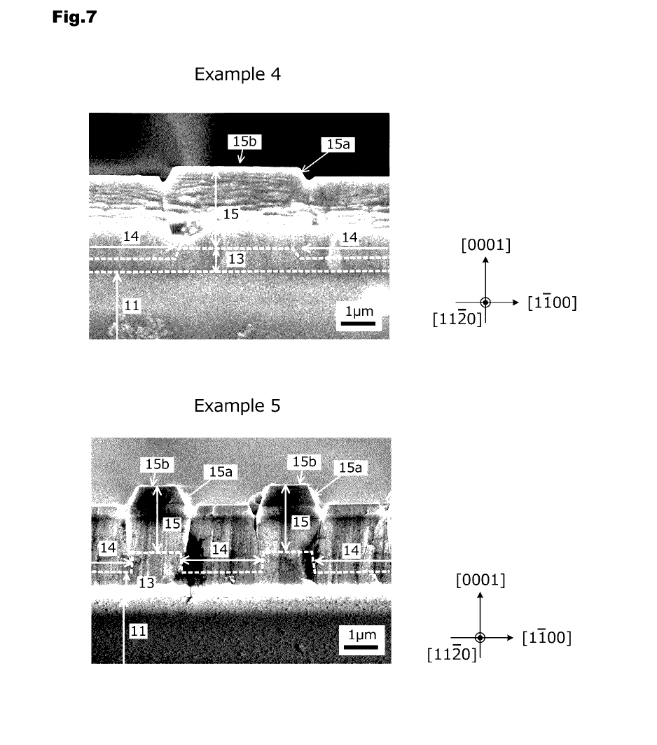

FIG. 7 is a SEM photograph of each of the elements of Example 4 and Example 5 and, as in FIG. 5A(a), is a cross-sectional SEM photograph taken when each element is cut in a plane formed by the [0001] direction and the [1-100] direction.

According to FIG. 7, when a ratio of an area is compared between a growth plane 15a parallel to a [1-101] plane and a growth plane 15b parallel to a [0001] plane, it is found that the rate of the growth plane 15a in Example 5 is higher than that in Example 4. That is, as the depth of the groove portion 14 is increased and as the width and interval of the groove portions 14 are reduced, a ratio at which the growth plane 15a parallel to the [1-101] plane appears can be further increased when the second layer 15 is grown.

The present inventors confirmed that when the depth and interval of the groove portions 14 are suitably set, it is possible to form the second layer 15 having only the growth plate 15a parallel to the [1-101] plane without having the growth plane 15b parallel to the [0001] plane.

<Verification Summary>

The above verifications show that after the groove portion 14 along the [11-20] direction is formed with such a depth that the surface of the growth substrate 11 is not exposed in Step S3, the second layer 15 is grown in Step S4, whereby the growth plane 15a parallel to the [1-101] plane and the growth plane 15b parallel to the [0001] plane are allowed to appear. When the second layer 15 is grown in such a state that the depth, width, interval of the groove portions 14 are suitably adjusted, the second layer 15 having only the growth plane 15a parallel to the [1-101] plane can be formed.

In the above verifications, although the direction of the groove portion 14 is the [11-20] direction, the same phenomenon is expressed in the case where the direction of the groove portion 14 is a direction crystallographically equivalent to the [11-20] direction, that is, a [1-210] direction, a [−2110] direction, a [−1-120] direction, a [−12-10] direction, or a [2-1-10] direction.

Step S4 corresponds to the step (d).

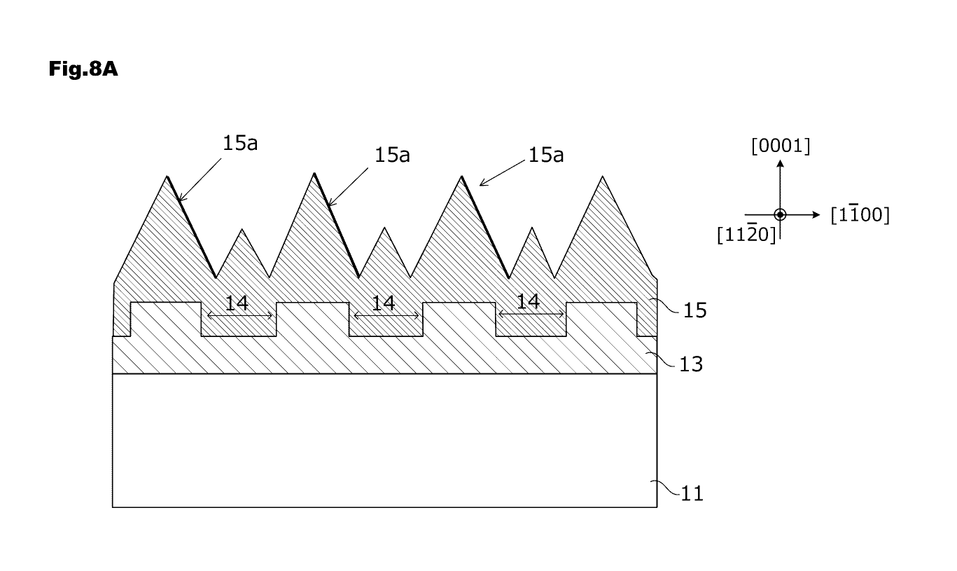

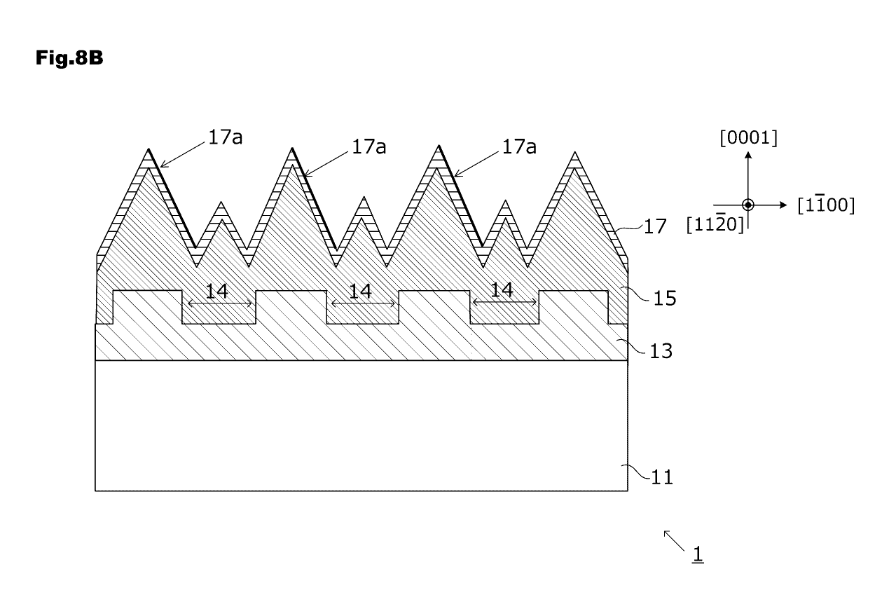

As described above in Step S4, when the depth, width, interval of the groove portions 14 are suitably adjusted, the second layer 15 having only the growth plane 15a parallel to the [1-101] plane can be formed (see FIG. 8A). Accordingly, when the active layer 17 is grown after the second layer 15 is grown, the semiconductor light emitting element 1 including the active layer 17 having only the growth plane 17a parallel to the {1-101} plane can be manufactured (see FIG. 8B). Since processes after the state of FIG. 8B have been already described above, they are omitted.

According to the semiconductor light emitting element 1 shown in FIG. 8B, the active layer 17 is configured to have only the growth plane 17a parallel to the {1-101} plane without having the growth plane 17b parallel to the {0001} plane. Thus, since the semiconductor light emitting element 1 including the active layer 17 which is not or almost not affected by the internal electric field is achieved, the light emitting efficiency is more extremely enhanced than conventional one. In particular, even when the semiconductor light emitting element is used as a short-wavelength and high-current drive light source including an ultraviolet region, high light emitting efficiency is demonstrated.

(Step S5)

An active layer 17 is continuously grown on an upper surface of the second layer 15 having the growth plane 15a parallel to the {1-101} plane and the growth plane 15b parallel to the {0001} plane (see FIG. 1). As one example of a specific method, a process in which the in-furnace temperature of the MOCVD device is set to not less than 900° C. and not more than 1600° C., and while nitrogen gas and hydrogen gas as carrier gasses are flown, TMA and ammonia as raw material gasses are supplied into the treatment furnace for a predetermined time according to a film thickness; and a process in which TMA, TMG, and ammonia as raw material gasses are supplied into the treatment furnace for a predetermined time according to a film thickness are repeated a predetermined number of times according to a periodic number. According to this configuration, the active layer 17 made of Alₓ₃Ga₁₋ₓ₃N (0<x3≦1)/AlN in multiple cycles is formed.

When Alₓ₃Ga_{y3}In_{1-x3-y3}N (0<x3≦1, 0≦y3≦1)/Alₓ₄Ga_{y4}In_{1-x4-y4}N (0<x4≦1, 0≦y4≦1) is used as the active layer 17, TMA, ammonia, TMG, and TMI may be supplied as raw material gasses at a predetermined flow rate corresponding to the composition.

In Step S4, since the second layer 15 having the growth plane 15a parallel to the {1-101} plane and the growth plane 15b parallel to the {0001} plane is formed, when epitaxial growth is performed in this state in Step S5, the active layer 17 having the growth plane 17a parallel to the {1-101} plane and the growth plane 17b parallel to the {0001} plane is formed.

Step S5 corresponds to the step (e).

(Following Steps)

When the semiconductor light emitting element 1 is used as the electron-beam-pumped light source device 90, as described with reference to FIGS. 2 (a) to 3, the semiconductor light emitting element 1 is disposed at a predetermined position in the vacuum vessel 40, and the electron beam source 60 and the light transmission window 45 are further disposed, whereby this configuration is achieved.

(Configuration and Manufacturing Method of LED Element)

The semiconductor light emitting element 1 shown in FIG. 1 can be used as an LED element. Hereinafter, a configuration in the case where the semiconductor light emitting element 1 is used as the LED element and a manufacturing method thereof will be described.

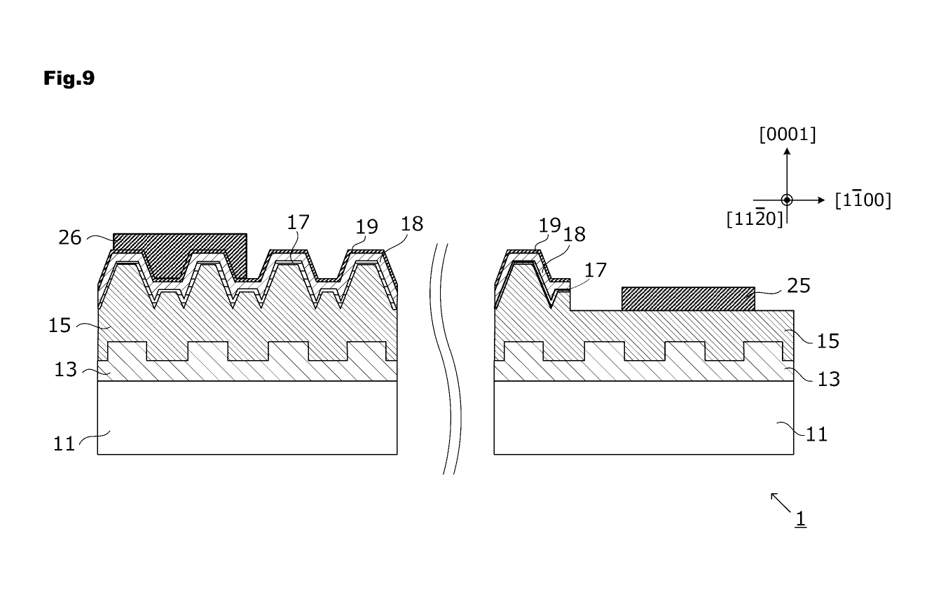

FIG. 9 is a schematic cross-sectional view of the semiconductor light emitting element 1 of FIG. 1 realized as an LED. When the semiconductor light emitting element 1 is realized as an LED, the second layer 15 is constituted as a semiconductor layer of a first conductive type (for example, n-type). As one example, the second layer 15 is made of n-type Alₓ₂Ga₁₋ₓ₂N (0<x2≦1).

The semiconductor light emitting element 1 shown in FIG. 9 includes an active layer 17, and for example, a p-type clad layer 18 formed on an upper layer of the active layer 17 and made of p-type Alₓ₄Ga₁₋ₓ₄N (0<x4≦1) and a p-type contact layer 19 formed on an upper layer of the p-type clad layer 18 and made of p⁺-type GaN. An n-side electrode 25 made of, for example, Ti/Al is formed on a portion of an exposed surface of the second layer 15 made of n-type Alₓ₂Ga₁₋ₓ₂N (0<x2≦1), and a p-side electrode 26 made of, for example, Ti/Au is formed on an upper layer of the p-type contact layer 19. Bonding wire (not shown) is applied to the n-side electrode 25 and the p-side electrode 26. In this embodiment, the p-type clad layer 18 and the p-type contact layer 19 correspond to a “third layer”, the n-side electrode 25 corresponds to a “first electrode”, and the p-side electrode 26 corresponds to a “second electrode”.

In the semiconductor light emitting element 1 shown in FIG. 9, when a voltage is applied to between the n-side electrode 25 and the p-side electrode 26, current is flown to the active layer 17, and electrons and holes are recombined to emit light having a predetermined wavelength. At this time, according to this configuration, since the active layer 17 has the growth plane 17a parallel to the {1-101} plane, the influence of the internal electric field is suppressed, and an LED with high light emitting efficiency is achieved. In this embodiment, since the active layer 17 has the growth plane 17b parallel to the {0001} plane in addition to the growth plane 17a parallel to the {1-101} plane, there is an effect that a plurality of light beams having different peak wavelengths can be emitted.

Next, a manufacturing method in which the semiconductor light emitting element 1 is used as an LED element will be described.

First, Steps S1 to S3 are executed as above. After that, in Step S4, methylsilane, tetraethylsilane, and the like for constituting an n-type impurity are contained as raw material gasses in addition to ammonia, TMA, and TMG. According to this configuration, the second layer 15 formed of an n-type semiconductor layer is formed. For example, the second layer 15 may be made of n-type Alₓ₂Ga₁₋ₓ₂N (0<x2≦1). For the same reason as above, the second layer 15 is formed to have the growth plane 15a parallel to the {1-101} plane and the growth plane 15b parallel to the {0001} plane.

After that, after the active layer 17 is grown in Step S5, the active layer 17 is further grown such that biscyclopentadienyl magnesium (Cp₂Mg) for constituting a p-type impurity is contained as a raw material gas in addition to ammonia, TMA, and TMG. According to this configuration, as shown in FIG. 9, the p-type clad layer 18 made of p-type Alₓ₄Ga₁₋ₓ₄N (0<x4≦1) is formed on the upper layer of the active layer 17. The flow rate of the raw material gas is changed, and the p-type contact layer 19 made of P⁺-type GaN is formed.

Next, a laminate of the p-type contact layer 19, the p-type clad layer 18, and the active layer 17 in a part of region is etched by ICP etching to expose a part of the upper surface of the second layer 15 formed of an n-type semiconductor layer. Then, the n-side electrode 25 made of, for example, Ti/Al is formed on the upper layer of the exposed second layer 15, and the p-side electrode 26 made of, for example, Ni/Au is formed on the upper layer of the p-type contact layer 19. Then, elements are separated from each other by, for example, a laser dicing device, and wire bonding is applied to an electrode.

### Another Embodiment

Another embodiment of the present invention will be described.

<1> In the first embodiment, it has been described that the groove portion 14 parallel to the <11-20> direction of the first layer 13 is formed in Step S3. In particular, in Examples and Comparative Examples, it has been described that the extending direction of the groove portion 14 is the [11-20] direction.

However, when the extending direction of the groove portion 14 is the <11-20> direction, that is, the [11-20] direction and a direction crystallographically equivalent to the [11-20] direction, the above effects are achieved by the same principle.

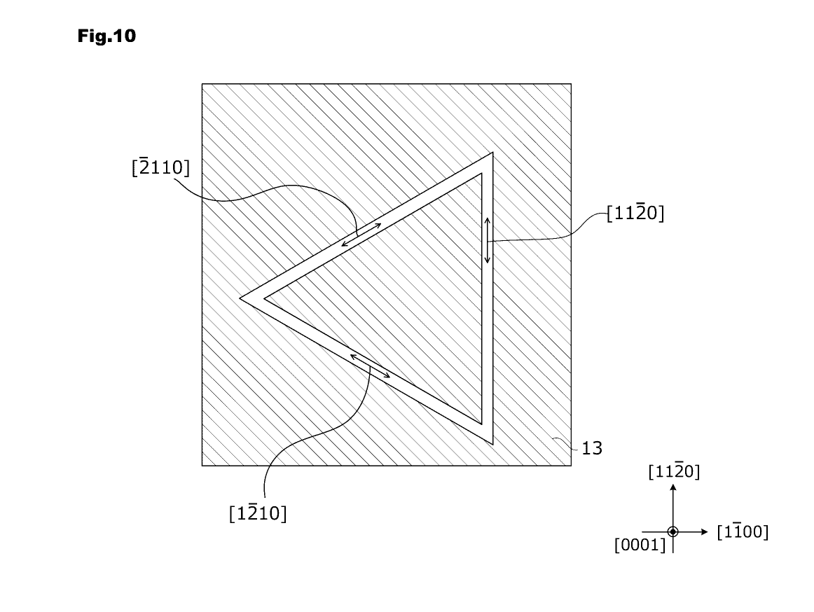

FIG. 10 is a top view in one step in a method for manufacturing a semiconductor light emitting element 1 of another embodiment and schematically shows a state of the element after execution of Step S3 as viewed from a [0001] plane. Thus, as shown in FIG. 10, for example, a groove portion 14 extending in three different directions equivalent to a <11-20> direction, that is, a [11-20] direction (or a [−1-120] direction), a [1-210] direction (or a [−12-10] direction), and a [−2110] direction (or a [2-1-10] direction) may be formed in Step S3. The number of the groove portions 14 is suitably set.

<2> As described above in the section “Problems to be solved by the invention”, Al has a characteristic of high in reactivity. Thus, when an element is manufactured by the method described in Patent Document 1, although a plane other than the c-plane (0001) plane is allowed to serve as a growth plane in the case of GaN, such a growth plane cannot be obtained in AlN or AlGaN.

On the other hand, in each of the elements of Examples, although both the first layer 13 and the second layer 15 are made of AlN, the second layer 15 could be grown to have the growth plane 15a parallel to the {1-101} plane. This suggests that according to the present method, also in a nitride semiconductor layer containing highly reactive Al with high composition, the second layer 15 can be grown to have the growth plane 15a parallel to the {1-101} plane. That is, even if the second layer 15 is made of, in addition to AlN, AlGaN or AlInGaN, a similar effect is achieved. The same holds for the first layer 13.

<3> As the application using the semiconductor light emitting element 1, although the LED and the electron-beam-pumped light source device have been described above, mode for the use of the semiconductor light emitting element 1 is not limited to them. The configuration shown in each drawing is just an example, and the present invention should not be limited to the structures as shown in the drawings.

### DESCRIPTION OF REFERENCE SIGNS

1: semiconductor light emitting element
11: growth substrate
13: first layer
14: recess (groove portion)
15: second layer
15a: growth plane of second layer parallel to {1-101} plane
15b: growth plane of second layer parallel to {0001} plane
17: active layer
17a: growth plane of active layer parallel to {1-101} plane
17b: growth plane of active layer parallel to {0001} plane
18: p-type clad layer
19: p-type contact layer
25: n-side electrode
26: p-side electrode
40: vacuum vessel
41: vessel housing
45: light transmission window
60: electron beam source
61: support substrate
62: electron beam emitting portion
63: base portion
65: extraction electrode
66: electrode holding member
90: electron-beam-pumped light source device
101: conduction band
102: valence band
103: wave function of electrons
104: wave function of hole

1. A method for producing a semiconductor light emitting element, the method comprising:
a step (a) of preparing a growth substrate;
a step (b) of growing a first layer made of Alₓ₁Ga_{y1}In_{1-x1-y1}N (0<x1≦1, 0≦y1≦1) on an upper layer of the growth substrate in a <0001> direction;
a step (c) of forming a groove portion extending along a <11-20> direction of the first layer with respect to the first layer with such a depth that a surface of the growth substrate is not exposed;
after the step (c), a step (d) of growing a second layer, which is made of Alₓ₂Ga_{y2}In_{1-x2-y2}N (0<x2≦1, 0≦y2≦1), on an upper layer of the first layer with at least a {1-101} plane serving as a crystal growth plane; and
a step (e) of growing an active layer on an upper layer of the second layer.

2. The method for producing a semiconductor light emitting element according to claim 1, wherein the step (d) is a step of growing the second layer on an upper side of a region where the groove portion is formed and an upper side of a region where the groove is not formed with a slope to a principal surface of the growth substrate serving as a crystal growth plane.

3. The method for producing a semiconductor light emitting element according to claim 1, wherein the first layer is made of Alₓ₁Ga_{y1}In_{1-x1-y1}N (0.5≦x1≦1, 0≦y1≦1).

4. The method for producing a semiconductor light emitting element according to claim 3, wherein the first layer is made of AlN.

5. The method for producing a semiconductor light emitting element, according to claim 1, wherein the second layer is made of AlN.

6. The method for producing a semiconductor light emitting element according to claim 1, wherein the second layer is made of Alₓ₂Ga₁₋ₓ₂N.

7. The method for producing a semiconductor light emitting element according to claim 1, wherein after execution of the step (d), a crystal growth plane of the second layer includes a {1-101} plane and a {0001} plane.

8. The method for producing a semiconductor light emitting element according to claim 1, wherein after execution of the step (d), a crystal growth plane of the second layer includes only a {1-101} plane.

9. The method for producing a semiconductor light emitting element according to claim 1, wherein the step (c) is a step of forming the groove portion extending in two or more different directions belonging to the <11-20> direction.

10. A semiconductor light emitting element comprising:
a first layer made of Alₓ₁Ga_{y1}In_{1-x1-y1}N (0<x1≦1, 0≦y1≦1) with a {0001} plane serving as a crystal plane;
a second layer formed on an upper layer of the first layer and made of Alₓ₂Ga_{y2}In_{1-x2-y2}N (0<x2≦1, 0≦y2≦1); and
an active layer formed on an upper layer of the second layer,
wherein the first layer has a recess extending along a <11-20> direction on a surface on the second layer side, and
at least a portion of the active layer is formed on a {1-101} plane of the second layer.

11. The semiconductor light emitting element according to claim 10, wherein the second layer has a crystal growth plane including a slope to a principal surface of the growth substrate on an upper side of a region where the recess is formed and an upper side of a region where the recess is not formed, both of which are upper layers of the first layer.

12. The semiconductor light emitting element according to claim 10, wherein the first layer is made of Alₓ₁Ga_{y1}In_{1-x1-y1}N (0.5≦x1≦1, 0≦y1≦1).

13. The semiconductor light emitting element according to claim 10, wherein the first layer is made of AlN.

14. The semiconductor light emitting element according to claim 10, wherein the second layer is made of AlN.

15. The semiconductor light emitting element according to claim 10, wherein the second layer is made of Alₓ₂Ga₁₋ₓ₂N.

16. The semiconductor light emitting element according to claim 10, wherein the active layer is formed on the {1-101} plane of the second layer and the {0001} plane of the second layer.

17. The semiconductor light emitting element according to claim 10, wherein the active layer is formed only on the {1-101} plane of the second layer.

18. An electron-beam-pumped light source device comprising:
the semiconductor light emitting element according to claim 10; and
an electron beam source,
wherein the active layer emits light when an electron beam emitted from the electron beam source enters the active layer.

19. An LED element comprising:
the semiconductor light emitting element according to claim 10;
a third layer provided on an upper layer of the active layer and made of Alₓ₄Ga_{y4}In_{1-x4-y4}N (0<x4≦1, 0≦y4≦1) of any one of an n-type conduction type and a p-type conduction type;
a first electrode electrically connected to the second layer; and
a second electrode electrically connected to the third layer,
wherein the second layer is made of Alₓ₂Ga_{y2}In_{1-x2-y2}N of a conduction type different from Alₓ₂Ga_{y2}In_{1-x2-y2}N of a conduction type in the third layer.
